(19) United States
(12) Patent Application Publication
(10) Pub. No.: US 2019/0214843 A1
(43) Pub. Date: Jul. 11, 2019

(54) POWER STORAGE CONTROL DEVICE

(71) Applicant: OMRON Corporation, KYOTO (JP)

(72) Inventor: Hirokazu EHARA, OSAKA (JP)

(73) Assignee: OMRON Corporation, KYOTO (JP)

(21) Appl. No.: 16/161,098

(22) Filed: Oct. 16, 2018

(30) Foreign Application Priority Data
Jan. 9, 2018 (JP) 2018-001154

(51) Int. Cl. H02J 7/04; H02J 7/02

(52) U.S. Cl. CPC H02J 7/045; G01R 19/16547; H02J 7/022

(57) ABSTRACT

A power storage control device capable of charging a storage battery with a self-sustaining output of a PCS without the necessity of stopping a self-sustaining operation is provided. When a storage battery is charged with PCS's self-sustaining output, a control part generates a charging current command based on a standard charging current command, and controls the electric power conversion part according to the generated charging current command. The charging current command causes charging current command values in a predetermined range centered on “0” of the standard charging current command to approach “0”. The standard charging current command is time series data of the charging current command values designating a current extracted from the self-sustaining output of PCS, synchronized with

PCS's self-sustaining output, and has an amplitude corresponding to a target value of electric power charged to the storage battery.

### CROSS-REFERENCE TO RELATED APPLICATION

The present application is related to and claims priority from Japanese patent application no. 2018-001154, filed on Jan. 9, 2018. The entire contents of the aforementioned application are hereby incorporated by reference herein.

### BACKGROUND

### Technical Field

The disclosure relates to a power storage control device.

### Description of Related Art

In a power storage control device that controls a storage battery, there exists self-sustaining output terminal (for example, refer to Japanese Laid Open 2018-085855). In addition, as shown in FIG. 1, as a power storage control device, an apparatus connected to a self-sustaining output terminal 41 of a power conditioner (PCS) 40 and configured to supply electric power in a storage battery 30 to a self-sustaining operation load 45 when the self-sustaining output power of the PCS 40 is insufficient upon power failure of a system 50 is known.

In such a power storage control device, a self-sustaining operation of the power storage control device should be stopped when a self-sustaining output voltage (an effective value) of the PCS 40 is lower than a predetermined voltage.

The inventors of the present disclosure conducted intensive research in order to realize a high-performance power storage control device, and found the following.

(a) When a storage battery 30 is charged by a self-sustaining output of a PCS 40, in a case in which an electrical power charged to the battery 30 is relatively small, as shown in FIG. 2A, a sine wave voltage is output from a self-sustaining output terminal 41 of the PCS 40. Further, a certain charging current command shown in FIG. 2A and FIG. 2B, which will be described below, is information that is generated in the power storage control device and designates a current extracted from the self-sustaining output of the PCS.

(b) When the charging electric power to the battery 30 is increased, as shown in FIG. 2B, a self-sustaining output voltage waveform of the PCS 40 is distorted, and as a result, an effective value of a self-sustaining output voltage of the PCS 40 may be lower than the predetermined voltage (i.e., the necessity of stopping a self-sustaining operation of the power storage control device may occur).

Here, the disclosure is directed to providing a power storage control device capable of charging a battery with a self-sustaining output of a PCS without the necessity of stopping a self-sustaining operation.

### SUMMARY

In order to accomplish the objective, a power storage control device according to an aspect of the disclosure includes an electric power conversion part having a direct current input/output terminal and an alternating current input/output terminal that are connected to a storage battery; a connection circuit part that is capable of forming a state in which the alternating current input/output terminal of the electric power conversion part is connected to a system and a state in which the alternating current input/output terminal of the electric power conversion part is connected to a self-sustaining output terminal of a power conditioner (PCS); and a control part configured to control the electric power conversion part. When the storage battery is charged with a self-sustaining output of the PCS, the control part generates a charging current command based on a standard charging current command, and controls the electric power conversion part according to the generated charging current command, in which the charging current command causes charging current command values in a predetermined range centered on “0” of the standard charging current command to approach “0”. The standard charging current command is time series data of the charging current command values that designate a current extracted from the self-sustaining output of the PCS, synchronized with a self-sustaining output of the PCS, and has an amplitude corresponding to a target value of an electric power charged to the storage battery.

### BRIEF DESCRIPTION OF THE DRAWINGS

FIG. 1 is a view for explaining a power storage control device that can be connected to a self-sustaining input terminal of a PCS.

FIG. 2A is a view (first) for explaining a problem occurring in a system using a conventional power storage control device.

FIG. 2B is a view (second) for explaining a problem occurring in a system using a conventional power storage control device.

FIG. 3 is a view for explaining a schematic configuration and a type of use of a power storage control device according to an embodiment of the disclosure.

FIG. 4 is a functional block diagram related to a charging current command generating function of a control part included in a power storage control device.

FIG. 5A is a view for explaining a charging current command generated in a control part.

FIG. 5B is a view for explaining a variant of the control part.

FIG. 5C is a view for explaining a variant of the control part.

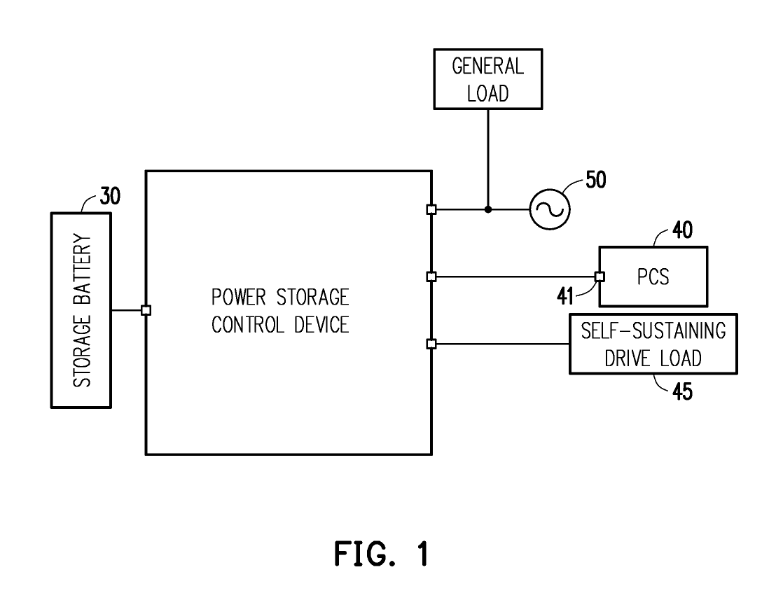

### DESCRIPTION OF THE EMBODIMENTS

Hereinafter, an embodiment of the disclosure will be described with reference to the accompanying drawings.

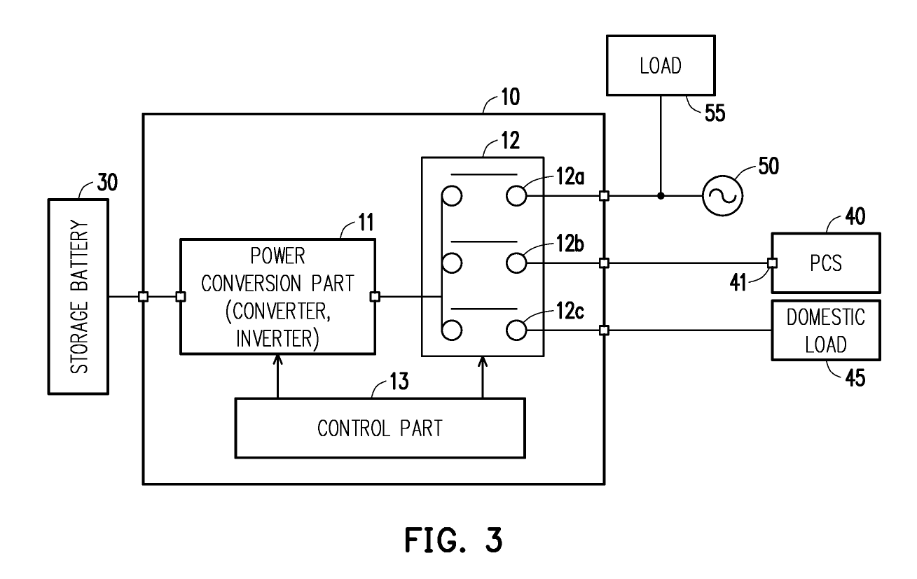

In FIG. 3, a schematic configuration and a type of use of a power storage control device 10 according to the embodiment of the disclosure are shown.

The power storage control device 10 according to the embodiment is a device connected to a system 50 and a general load 55, a self-sustaining output terminal 41 of a power conditioner (PCS) 40 for a solar cell array (not shown), a self-sustaining operation load 45 and a storage battery 30. Here, the general load 55 is a conventional domestic load (electric appliances), and the self-sustaining operation load 45 is a domestic load that is a supply target of electric power upon power failure of the system 50.

As shown in FIG. 3, the power storage control device 10 includes an electric power conversion part 11, a connection circuit part 12 and a control part 13.

The electric power conversion part 11 is a part (an electronic circuit), in which a bidirectional DC/DC converter and a bidirectional DC/AC inverter are combined and capable of bidirectional conversion between a direct current and an alternating current. The electric power conversion part 11 has a direct current input/output terminal connected to the storage battery 30, and an alternating current input/output terminal connected to the system 50 or the like via the connection circuit part 12.

The connection circuit part 12 is a part including a relay 12a, a relay 12b and a relay 12c. The relay 12a is a relay to turn ON/OFF connection (electrical connection) between the electric power conversion part 11 and the system 50. The relay 12b is a relay to turn ON/OFF connection between the electric power conversion part 11 and the self-sustaining output terminal 41 of the PCS 40, and the relay 12c is a relay to turn ON/OFF connection between the electric power conversion part 11 and the self-sustaining operation load 45.

The control part 13 is a part to generally control the electric power conversion part 11 and the connection circuit part 12. The control part 13 includes a processor (a CPU, a microcontroller, or the like) and peripheral circuits thereof, and outputs of sensors (a current sensor, a voltage sensor, not shown) installed at respective locations in the power storage control device 10 are input to the control part 13.

Control performed to the connection circuit part 12 by the control part 13 is the same as control performed by a control part in a power storage control device in the related art (hereinafter, referred to as “a control part in the related art”) connected to the self-sustaining output terminal 41 of the PCS 40 and used therewith. That is, the control part 13 turns on the relay 12a during system interconnection, and turns on the relay 12b and the relay 12c during self-sustaining interconnection.

In addition, control performed to the connection circuit part 12 by the control part 13 is basically the same as control performed by “the control part in the related art.” However, in order to charge the storage battery 30 with the self-sustaining output of the PCS 40 without the necessity of stopping the self-sustaining operation, when the storage battery is charged with the self-sustaining output of the PCS, the control part 13 generates a charging current command that causes charging current command values in a predetermined range centered on “0” of a standard charging current command to approach “0”, and controls the electric power conversion part 11 based on the generated charging current command. As the standard charging current command that is time series data of a charging current command value that designates a current extracted from the self-sustaining output of the PCS 40, the standard charging current command is synchronized with the self-sustaining output of the PCS 40 and has an amplitude corresponding to a charging electric power target value.

Hereinafter, the function of the control part 13 will be described more specifically.

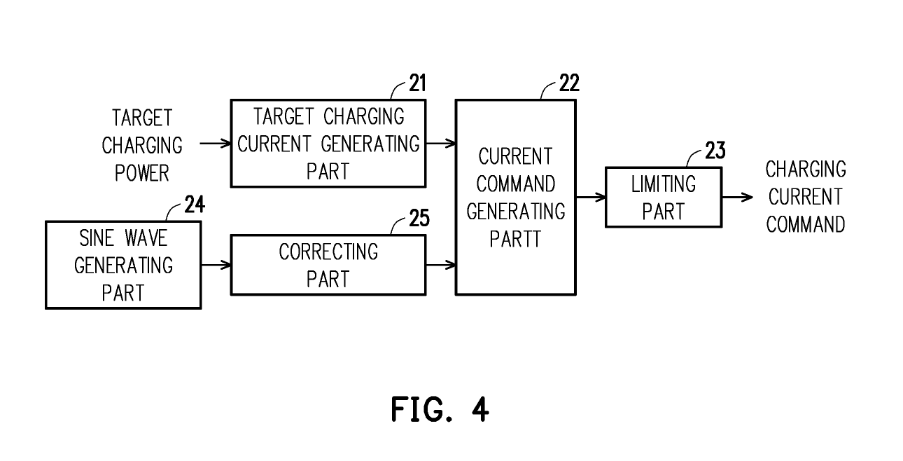

FIG. 4 shows a functional block diagram related to a charging current command generating function of the control part 13. As shown, the control part 13 generates a charging current command when the control part 13 functions as a target charging current generating part 21, a current command generating part 22, a limiting part 23, a sine wave generating part 24 and a correcting part 25.

The target charging current generating part 21 is a part to generate a target charging current (an effective value) by dividing a charging electric power target value [W] by 101 [V]. Here, the charging electric power target value is a value set by a user as a target value of an electric power charged to the storage battery 30. The sine wave generating part 24 is a part to output a sine wave having an amplitude of “1” synchronized with the self-sustaining output voltage of the PCS 40. The correcting part 25 is a part to perform correction processing (to be described below in detail) with respect to a sine wave from the sine wave generating part 24. The current command generating part 22 is a part to generate a charging current command by multiplying an output of the correcting part 25 by a target charging current from the target charging current generating part 21. The limiting part 23 is a part to convert a charging current command from the current command generating part 22 to a charging current command that falls into a current range from a -default value (for example, 15 A) to a default value.

Correction processing performed to a sine wave from the sine wave generating part 24 by the connecting part 25 is to output “0” when an input value is -SQR (2) or more and SQR (2) or less, and to output the input value directly when the input value is smaller than -SQR (2) and larger than SQR (2). In other words, when the sine wave from the sine wave generating part 24 is expressed as sin (θ), the correction processing is to output “0” when 0°≤θ≤45°, 135°≤θ≤225° or 315°≤θ≤360° is established, and to output sin (0) when the above condition is not established.

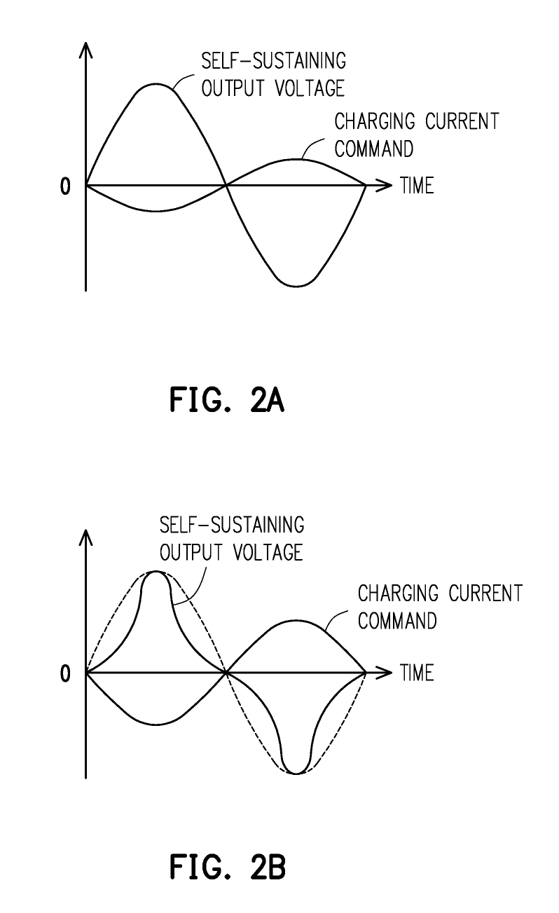

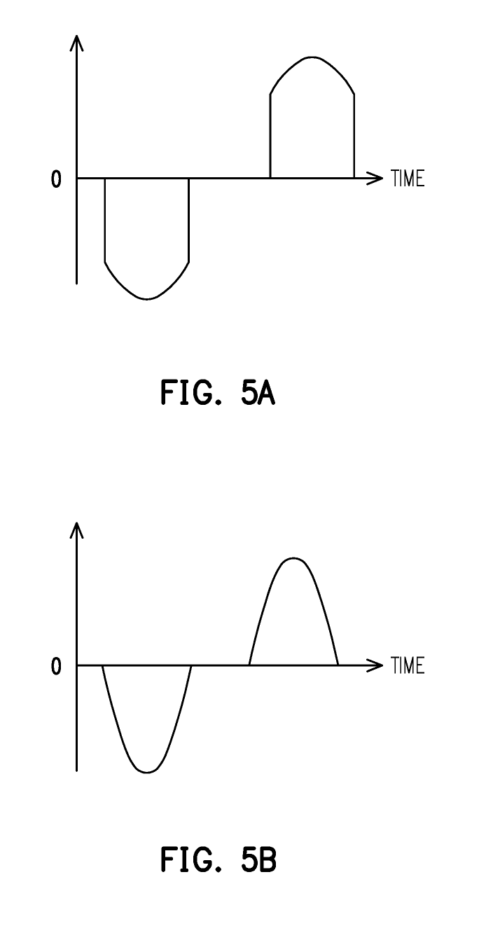

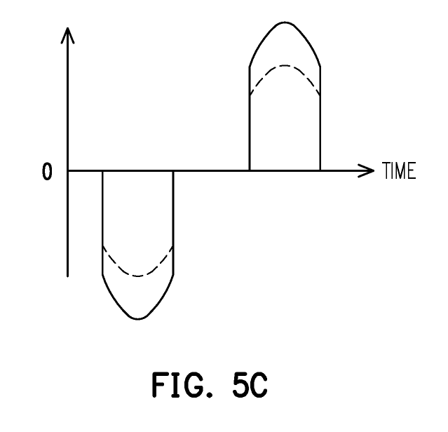

If the aforementioned correction processing is performed by the correcting part 25, when the charging electric power target value is not excessively large, a charging current command that temporally varies as shown in FIG. 5A is output from the limiting part 23. Then, distortion of the self-sustaining output voltage waveform of the PCS 40 as shown in FIG. 2B occurs due to a decrease of output performance in the vicinity of 0 V of the PCS 40, and the control part 13 controls the electric power conversion part 11 according to the charging current command output from the limiting part 23. Accordingly, according to the power storage control device 10 of the embodiment, the storage battery 30 can be charged with the self-sustaining output of the PCS 40 without the necessity of stopping the self-sustaining operation.

<Variants>

The above-mentioned power storage control device 10 is configured to perform various deformations. For example, when the electric power conversion part 11 is controlled according to the charging current command shown in FIG. 5A, the self-sustaining output voltage of the PCS 40 may be decreased due to an abrupt change in charging current command. For this reason, the control part 13 may be modified to generate a charging current command that temporally varies relatively gently as shown in FIG. 5B. In addition, when the electric power conversion part 11 is controlled according to the charging current command shown in FIG. 5A, the storage battery 30 is charged with an electric power smaller than the charging electric power target value. In order to charge the storage battery 30 with the greater electric power, the control part 13 may be configured to deform the charging current command shown in FIG. 5C, i.e., the charging current command (dotted lines) to generate a charging current command that increases in a current value direction such that the storage battery 30 is charged with the electric power according to the charging electric power target value.

The control part 13 may be deformed to generate the charging current command (correction processing to the sine wave from the sine wave generating part 24 is not performed) that temporally varies in a sine wave shape when a charging electric power target value set by a user is smaller than a preset threshold. In addition, the control part 13 may have a function of automatically determining an electric power amount that returns to charging, and determining a charging electric power target value based on the determination result.

Other Configurations

In one aspect of the disclosure, a power storage control device includes an electric power conversion part having a direct current input/output terminal and an alternating current input/output terminal that are connected to a storage battery; a connection circuit part that is capable of forming a state in which the alternating current input/output terminal of the electric power conversion part is connected to a system and a state in which the alternating current input/output terminal of the electric power conversion part is connected to a self-sustaining output terminal of a power conditioner (PCS); and a control part configured to control the electric power conversion part. When the storage battery is charged with a self-sustaining output of the PCS, the control part generates a charging current command based on a standard charging current command, and controls the electric power conversion part according to the generated charging current command, in which the charging current command causes charging current command values in a predetermined range centered on “0” of the standard charging current command to approach “0”. The standard charging current command is time series data of the charging current command values that designate a current extracted from the self-sustaining output of the PCS, synchronized with a self-sustaining output of the PCS, and has an amplitude corresponding to a target value of an electric power charged to the storage battery.

That is, distortion of the self-sustaining output voltage waveform of the PCS 40 as shown in FIG. 2B occurs due to a decrease in output performance close to 0 V of the PCS 40. Accordingly, according to the power storage control device having the above-mentioned configuration, the storage battery can be charged with the self-sustaining output of the PCS without the necessity of stopping the self-sustaining operation.

Various aspects having specific configurations (functions) may be employed for the control part of the power storage control device according to the aspect of the disclosure. For example, the control part may “generate the charging current command that sets the charging current command values in the predetermined range centered on “0” of the standard charging current command as “0” when the storage battery is charged with the self-sustaining output of the PCS.” In addition, the control part may “generate a charging current command that causes the charging current command values in the predetermined range entered on 0” of the standard charging current command to approach “0”, and causes other charging current command values to increase in a current value direction so that the storage battery is charged with the same electric power as when the electric power conversion part is controlled according to the standard charging current command, when the storage battery is charged with the self-sustaining output of the PCS″ or may “generate the charging current command in which each current command value falls within a predetermined current range”.

According to the disclosure, it is possible to provide a power storage control device capable of charging a storage battery with a self-sustaining output of a PCS without the necessity of stopping a self-sustaining operation.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A power storage control device, comprising:
an electric power conversion part, having a direct current input/output terminal and an alternating current input/output terminal that are connected to a storage battery;
a connection circuit part, capable of forming a state that the alternating current input/output terminal of the electric power conversion part is connected to a system and a state that the alternating current input/output terminal of the electric power conversion part is connected to a self-sustaining output terminal of a power conditioner (PCS); and
a control part, controlling the electric power conversion part,
wherein when the storage battery is charged with a self-sustaining output of the PCS, the control part generates a charging current command based on a standard charging current command, and controls the electric power conversion part according to the generated charging current command, in which the charging current command causes charging current command values in a predetermined range centered on “0” of the standard charging current command to approach “0”,
the standard charging current command is time series data of the charging current command values that designate a current extracted from the self-sustaining output of the PCS, synchronized with a self-sustaining output of the PCS, and has an amplitude corresponding to a target value of an electric power charged to the storage battery.

2. The power storage control device according to claim 1, wherein when the storage battery is charged with the self-sustaining output of the PCS, the control part generates the charging current command that sets the charging current command values in the predetermined range centered on “0” of the standard charging current command as “0”.

3. The power storage control device according to claim 1, wherein when the storage battery is charged with the self-sustaining output of the PCS, the control part generates a charging current command that causes the charging current command values in the predetermined range entered on 0″ of the standard charging current command to approach “0”, and causes other charging current command values to increase in a current value direction so that the storage battery is charged with the same electric power as when the electric power conversion part is controlled according to the standard charging current command.

4. The power storage control device according to claim 2, wherein when the storage battery is charged with the self-sustaining output of the PCS, the control part generates a charging current command that causes the charging current command values in the predetermined range entered on 0″ of the standard charging current command to approach “0”, and causes other charging current command values to increase in a current value direction so that the storage battery is charged with the same electric power as when the electric power conversion part is controlled according to the standard charging current command.

5. The power storage control device according to claim 1, wherein the control part generates the charging current command in which each charging current command value falls within a predetermined current range.

6. The power storage control device according to claim 2, wherein the control part generates the charging current command in which each charging current command value falls within a predetermined current range.

7. The power storage control device according to claim 3, wherein the control part generates the charging current command in which each charging current command value falls within a predetermined current range.

8. The power storage control device according to claim 4, wherein the control part generates the charging current command in which each charging current command value falls within a predetermined current range.
